(19) United States
(12) Patent Application Publication
(10) Pub. No.: US 2015/0028724 A1
(43) Pub. Date: Jan. 29, 2015

(54) SINGLE CRYSTALLINE MICROSTRUCTURES AND METHODS AND DEVICES RELATED THERETO

(71) Applicant: Etrema Products, Inc., Ames, IA (US)

(72) Inventors: Eric Summers, Ankeny, IA (US); Rob Meloy, Marshalltown, IA (US)

(21) Appl. No.: 14/384,609

(22) PCT Filed: Jan. 31, 2013
(86) PCT No.: PCT/US2013/024128

§ 371 Date: Sep. 11, 2014

Related U.S. Application Data
(60) Provisional application No. 61/610,256, filed on Mar. 13, 2012.

(51) Int. Cl. C30B 29/52; C30B 33/02; H01F 1/147; B22D 7/00; H02N 2/18; C22C 38/12; C22C 33/04; C21D 1/26; C21D 6/00; C21D 9/46; C30B 11/02; C22C 38/00

(52) U.S. Cl. CPC C30B 29/52; C30B 11/02; C30B 33/02; H01F 1/147; B22D 7/00; C22C 38/002; C22C 38/12; C22C 33/04; C21D 1/26; C21D 6/00; C21D 9/46; H02N 2/186
USPC 310/339; 428/544; 428/682; 428/34.1; 420/127; 148/540; 148/543; 148/320

(57) ABSTRACT

A product, such as one or more thin sheets, each containing a single or near-single crystalline inclusion-containing magnetic microstructure, is provided. In one embodiment, the inclusion-containing magnetic microstructure is a Galfenol-carbide microstructure. Various methods and devices, as well as compositions, are also described.

This application claims the benefit under 35 U.S.C. 119 (e) of U.S. Provisional Application Ser. No. 61/610,256 filed on Mar. 13, 2012, which applications and publications are hereby incorporated by reference in their entirety entireties.

### BACKGROUND

Many devices, such as actuators and sensors, rely on smart materials in an appropriate form factor to produce the desired result. However, many such materials either cannot be produced in the appropriate form factor and/or lack the desired texture or optimum performance, as the methods used to make them fail to impart the appropriate characteristics.

### SUMMARY

The inventors recognize the need for smart materials having an appropriate form factor with a desired fiber texture, e.g., η-fiber texture, for optimum performance. In one embodiment, a product comprising one or more thin sheets, each containing a single or near-single crystalline inclusion-containing magnetic microstructure is provided. In one embodiment, the inclusion-containing magnetic microstructure is a Galfenol-carbide microstructure.

In one embodiment, a method of making one or more thin sheets is provided comprising melting one or more form factor components with a dopant, a magnetic material, a magnetic material performance enhancer and a precipitate former to produce a melted alloy; casting the melted alloy into a mold to produce at least one ingot; optionally further processing the at least one ingot; thickness reducing and annealing the at least one ingot to produce one or more annealed sheets; and texture annealing the one or more annealed sheets to produce the one or more thin sheets, each containing a single or near-single crystalline inclusion-containing magnetic microstructure.

In one embodiment, a method of increasing performance of one or more magnetic thin sheets is provided comprising adding one or more form factor components, a dopant, a magnetic material performance enhancer and a precipitate former to a magnetic material to produce a melted alloy; casting the melted alloy into a mold to produce one or more ingots; optionally further processing the one or more ingots; thickness reducing and annealing the one or more ingots to produce one or more annealed sheets; and texture annealing the one or more annealed sheets to produce one or more magnetic thin sheets, each containing a single or near-single crystalline inclusion-containing magnetic microstructure.

In one embodiment, a composition is provided comprising a magnetic microstructure having a composition formula of (Fe—Ga—Al—Mo—Ge—Sn—Si—Be)ₐ(Nb_{d}—Ti_{d}—Mo_{d}—Ta_{d}—W_{d})_{b}(C—N—B—S)_{c} wherein a≧98, b≦1, c≦1, d≦2, and (a+b+c=100). In one embodiment, d=1 or 2. In one embodiment, the composition comprises (Fe—Ga)₉₉(Nb)_{0.5}(C)_{0.5}.

In one embodiment, a device is provided comprising a thin sheet or a group of thin sheets, each containing a single or near-single crystalline inclusion-containing magnetic microstructure. The device can include, for example, an actuator, sensor or energy harvester, which operate at high frequencies, such as up to about 20 kHz, or higher, such as up to 50 kHz. Such devices can be used in a broad range of applications, such as in the medical device field (e.g., actuator actuating a blade to cut tissue and bone), manufacturing plants (e.g., attached to vibrating motors to harvest the vibrational energy to power wireless sensor networks within the plant), and the like.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 shows a conventional Scanning Electron Microscope (SEM)/Electron Back-Scatter Defraction (SEM/EBSD) image of a sheet of Galfenol without inclusions.

FIG. 2 is a flow diagram showing a method of producing a thin sheet containing single or near-single crystalline inclusion-containing magnetic microstructure according to an embodiment.

FIG. 3 is a flow diagram showing a method of thickness reducing and annealing the ingot of FIG. 2 according to an embodiment.

FIG. 4 is a flow diagram showing a method of further processing the ingot of FIG. 2 according to an embodiment.

FIG. 5 is a graph showing a generic magnetostriction (ppm) versus rotation angle (Deg) curve according to various embodiments.

FIG. 6 shows a macroscopic image of a portion of a texture annealed sheet produced in Example 1, with the locations of test samples (solid lines) indicated for SEM/EBSD and magnetostriction, respectively, according to various embodiments.

FIG. 7 (200×) shows an SEM/EBSD image of the magnetostriction sample area indicated in FIG. 6 according to an embodiment.

FIG. 8 is a histogram showing the misorientation angle between the eta (η)-fiber texture and the rolling direction (RD) (i.e., hereinafter “misorientation”) for the grain shown in FIG. 7 according to various embodiments.

FIG. 9 shows a pole figure analysis for the grain shown in FIG. 7 according to various embodiments.

FIG. 10 shows the macroscopic image of a portion of the texture annealed sheet produced in Example 2, with the locations of test samples (dashed lines) indicated for magnetostriction and texture (SEM/EBSD) analysis, respectively, according to various embodiments.

FIGS. 11A (500×) and 11B (1500×) show SEM images of the magneostriction sample area indicated in FIG. 10 according to an embodiment.

FIG. 12A shows an EBSD orientation imaging map (200×) of the grains in the magnetostriction sample area of FIG. 10 with the numbering “#1”, “#2,” and “#3” showing three different grain areas according to various embodiments.

FIG. 12B is a histogram showing the misorientation for the three grains shown in FIG. 12A according to various embodiments.

FIG. 13 shows a pole figure analysis for the three grains shown in FIG. 12B according to various embodiments.

FIG. 14 shows a macroscopic image of a portion of the texture annealed sheet produced in Example 3, with the locations of test samples (dashed lines) indicated for texture (SEM/EBSD) and magnetostriction (#1 and #2) analysis according to various embodiments.

FIG. 15 shows an EBSD orientation imaging map of the grains in the magnetostriction sample area of FIG. 14 with the numbering #1 (6° misorientation) and #2 (15° misorientation) showing two different grain areas according to various embodiments.

FIG. 16 is a histogram showing the misorientation for the two grains shown in FIG. 15 according to various embodiments.

FIG. 17 shows a pole figure analysis of the two grains shown in FIG. 15 according to various embodiments.

FIG. 18 shows the macroscopic image of a portion of the texture annealed sheet produced in Example 4, with the locations of test samples (solid lines) indicated for magnetostriction (“MS”) and SEM/EBSD (“A), respectively, according to various embodiments.

FIG. 19 shows an EBSD orientation imaging map of the grains in the magnetostriction sample area of FIG. 18 with the numbering “#1”, “#2,” and “#3” showing three different grain areas according to various embodiments.

FIG. 20 is a histogram showing the misorientation for the three grains shown in FIG. 19 according to various embodiments.

FIG. 21 shows a pole figure analysis for the three grains shown in FIG. 19 according to various embodiments.

FIG. 22 (150×) is an SEM image from a microprobe analysis of a sample from the area marked as “MS” in FIG. 19 according to an embodiment.

FIG. 23 is a texture analysis (SEM/EBSD) of the texture annealed sheet produced in Example 5.

FIG. 24 is a histogram showing the misorientation for the grains shown in FIG. 23.

FIG. 25 shows a pole figure analysis for the grains shown in FIG. 23.

FIG. 26 is a graph showing measured saturation magneostriction versus misorientation angle for several representative samples according to various embodiments.

### DETAILED DESCRIPTION OF THE EMBODIMENTS

In the following detailed description of embodiments of the invention, embodiments are described in sufficient detail to enable those skilled in the art to practice them, and it is to be understood that other embodiments may be utilized and that chemical and procedural changes may be made without departing from the spirit and scope of the present subject matter. The following detailed description is, therefore, not to be taken in a limiting sense, and the scope of embodiments of the present invention is defined only by the appended claims. The Detailed Description that follows begins with a definition section followed by a brief overview of Galfenol, a description of the embodiments, an example section and a brief conclusion.

The term “ingot” as used herein refers to an intermediate product cast into a shape suitable for further processing.

The term “sheet” as used herein refers to an ingot which has been further processed such as by rolling.

The term “smart material” refers to a material that has one or more properties that can be changed in a controlled fashion by external stimuli, such as stress, temperature, moisture, pH, electric or magnetic fields.

The term “magnetostriction” as used herein refers to a property of ferromagnetic materials that causes them to change their shape or dimensions when exposed to a magnetic field, as a result of a change in the magnetostrictive strain of the material. The variation of a material's magnetization due to the applied magnetic field changes the magnetostrictive strain until reaching its saturation value, λ. A magnetostrictive material is a type of smart material. When used without qualification herein, the term “magnetostriction” is intended to refer to “saturation magnetostriction.”

The term “eddy current losses” as used herein refers to currents generated in an electrical conductor, such as a magnetostrictive material, when exposed to changing magnetic fields or AC conditions. Such currents induce the formation of internal magnetic fields which oppose the externally changing magnetic field, thus reducing the efficiency of the magnetostrictive material.

The term “Galfenol” as used herein, refers to an alloy comprised primarily of iron and gallium.

The term “soft” as used herein refers to a magnetic material having a coercivity below 1 kA/m (12.5 Oe) or that requires a low magnetic field (i.e., <1000 Oe) to achieve saturation.

The term “energy harvester” as used herein, refers to a device that harvests energy from its environment. Solar cells and wind turbines are examples of energy harvesters. Vibrations from pumps, motors, blowers, and the like, can be converted into electrical energy using a vibration-based energy harvester made from a magnetostrictive material.

The term “fiber texture” or “texture” or “eta (η)-fiber texture” as used herein, refers to crystallographic orientation. For Galfenol, the desired fiber texture is <001> parallel to the applied magnetic field or stress direction, as defined by Miller Indices notation. For body-centered cubic (bcc) metals, such as Galfenol, this texture is also defined as the “eta (η)-fiber texture.”

The term “rolling direction” or “(RD)” as used herein, refers to the direction in the plane of a sheet of rolled metal which is perpendicular to the axes of the rolls during rolling, i.e., the transverse direction.

The term “fiber texture misorientation (Eta (η))” or “fiber texture misorientation angle” or “misorientation” as used herein refers to the difference, in degrees, between the eta (η)-fiber texture grains (i.e., eta (η)-fiber texture) and the rolling direction (RD). A weak misorientation is less than about 15 degrees. A moderate “misorientation is between about 16 and about 30 degrees. A strong misorientation is at least about 31 degrees.

The term “thin” as used herein refers to a material having a thickness less than 0.110 in (2.8 mm).

The term “near-single crystal” as used herein, refers to a microstructure containing a few small grains contained within a larger single crystalline area. As such a “near-single crystalline thin sheet” refers to a thin sheet containing such a microstructure.

The term “pour temperature” or “pour point” as used herein, refers to a superheated temperature at which molten metal can be poured into and substantially fill a mold. This is different than “melt temperature” which is a lower temperature at which a solid changes state from solid to liquid.

The term “tramp elements” as used herein refers to impurity elements contained in iron ore which are not removed during the process of converting the iron ore to shim stock. Tramp elements can include many different elements across the periodic table and are typically <10 ppmw in concentration.

The term “shim stock” as used herein refers to a thin (<0.031 in (0.079 cm)) sheet of metal (e.g., aluminum, brass, low carbon steel, etc.). 1008-1010 low carbon steel is one example of shim stock.

The term “dopant” as used herein refers to element(s) added to a substance to alter properties of the substance. In the case of a crystalline substance, atoms of the dopant can take the place of elements that were in the crystal lattice of the material or fit within spaces created by the periodicity of the crystal lattice. When used in an alloy system prior to a melting step, the dopant remains dispersed throughout the matrix (mixture) in subsequent processing steps.

The term “inclusion” as used herein refers to a particle intentionally included in a material to alter its properties. An inclusion is formed from a combination of added dopant and a precipitate former. Examples include, but are not limited to, metal oxides, nitrides, carbides, calcides or sulfides. As such, and in contrast to conventional use of the term “inclusion” as a reference to an undesirable foreign particle, the term “inclusion” as used herein is intended to refer to a desirable precipitate.

The term “Multiples of Uniform Density” or “(MUD)”, as used herein, refers to a measure of the strength of the clustering of poles (crystallographic planes or directions) relative to that from a random distribution. MUD values are a normalized value, thus allowing for direct comparisons between different data sets. Larger MUD values indicate a stronger degree of texture when comparing data sets.

The term “Abnormal Grain Growth” or “AGG” as used herein, refers to discontinuous grain growth. Abnormal grain growth can result in a microstructure dominated by a few very large grains. A weak AGG has less than 35 area % of the microstructure with the desired fiber texture. A moderate AGG has between 35% area % and 50 area % of the microstructure with the desired fiber texture. A strong AGG has greater than 50 area % of the microstructure with the desired fiber texture.

Utilizing the Joule Effect, a magnetic field can be applied to Galfenol with the material responding with a known, controllable change in shape or dimension. The magnetic field can be oscillated from DC up into the kHz range with the Galfenol strain response oscillating at this same frequency. Utilizing the Villari Effect, Galfenol responds to an externally applied stress with a change in magnetization in the material.

As such, Galfenol can be used as a sensor for sensing changes in mechanical states (stress, strain, and force), as an actuator and as an energy harvester. In energy harvesting, an oscillating mechanical stress from a pump motor, for example, can be coupled to a Galfenol-containing material with the resulting oscillating magnetization change in the Galfenol converted into electrical energy for immediate use by alarms or other sensors or stored in an energy storage device, such as a battery or capacitor for future use.

A well-defined crystallographic orientation (e.g., fiber texture) allows a Galfenol material to respond favorably to the above conditions. This characteristic helps to offset the anisotropy present in Galfenol (and other soft magnetostrictive materials). For Galfenol the desired fiber texture to produce these favorable results is <001> parallel to an applied magnetic field or stress direction, η-fiber texture, as defined by Miller Indices notation.

Maximum efficiency (minimal eddy current losses) in Galfenol allows for proper operation of an actuator, sensor, or energy harvester. Eddy current losses can be minimized by selecting an appropriate form factor of less than one skin-depth, defined as:

$$δ \approx \sqrt{\frac{2}{{ωσμ}_{0} {μ}_{r}}}$$

wherein ω=radial frequency (2πf), σ=electrical conductivity, μ₀=permeability of empty space, and μᵣ=relative permeability of the material. Such form factors include, for example, a sheet, wire, thin film, or powder of the appropriate thickness or diameter. As an example, a sheet thickness or wire diameter of less than 0.015 in (0.381 mm) is useful for minimizing eddy current losses in Galfenol operating at 20 kHz or below as an actuator, sensor, or energy harvester.

Directional solidification manufacturing routes have been developed for producing Galfenol with the desired η-fiber texture in rod form (e.g., Bridgman and Free Stand Zone Melt (FSZM) methods. However, expensive post-solidification processing steps are required to laminate the Galfenol to a form factor of less than one-skin depth. Conventional metal forming methods, such as rolling and wire drawing, can also be used to produce Galfenol in the appropriate form-factor. However, these methods lack the development of the desired n-fiber texture for optimum performance.

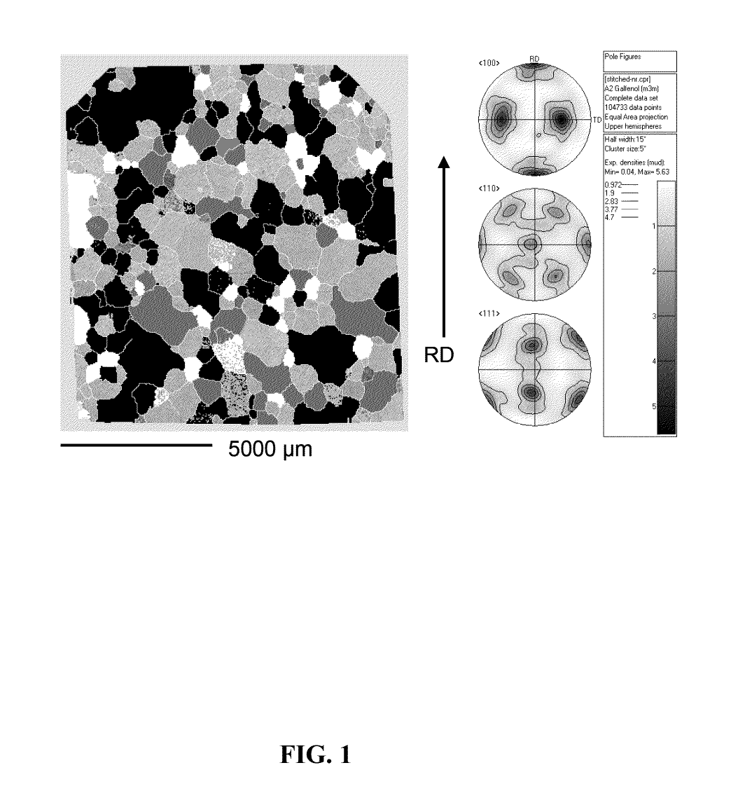

Attempts have been made to roll Galfenol into sheet form. However, the results are not satisfactory, with a saturation magnetostriction no more than 154 ppm and a low-to-moderate texture development with only 38 area % of the sample having an eta (η)-fiber texture misoriented 30 degrees or less from the rolling direction, as demonstrated by EBSD. One example of a microstructure and pole figures (i.e. fiber texture analysis) obtained without the presence of inclusions is shown in FIG. 1. In FIG. 1, the eta (η)-fiber texture oriented grains are colored in black and encompass 38 area % of this sample. The maximum MUD value of 5.63 from pole figures suggests a weak texture. See E. Summers, R. Meloy, Suok-Min Na, “Magnetostriction and texture relationships in annealed Galfenol alloys”, Journal of Applied Physics, Volume 105, 2009, 07A922, Feb. 19, 2009.

The various embodiments described herein provide an inclusion-containing magnetic material which contains single crystalline or near-single crystalline magnetostrictive microstructures with a desired fiber texture, such as a desired eta η-fiber texture comprised of properly oriented grains. Various embodiments further provide methods of making and using the materials, as well as devices containing these microstructures. In one embodiment, the magnetostrictive microstructure comprises Galfenol.

The ability to produce single crystalline or near-single crystalline magnetostrictive microstructures with the desired properties is surprising, since the use of dopants to form inclusions during processing has heretofore been considered to be undesirable due to the negative impact on the resulting materials. In conventional transformer steel (i.e., electrical steel) making processes, for example, carbon dopant addition is usually avoided since it can negatively affect the transformer performance of the material. As such, conventional wisdom teaches away from the intentional adding of dopants in the formation of single crystalline or near-single crystalline microstructures.

In contrast, the various embodiments described herein include a product made by intentionally adding a dopant in a desired amount to produce inclusion-containing microstructures with the desired properties. In one embodiment, the dopant is carbon (C). In one embodiment, the dopant combines with a precipitate former present in the matrix (i.e., mixture of starting components) to form an inclusion (e.g., a carbide inclusion) in the final product. In one embodiment, the precipitate former is Nb and the resulting inclusion is niobium carbide (NbC and/or Nb₂C). The presence of at least an amount of Nb₂C rather than a material containing only NbC may result in improved performance of the material.

Known grain-oriented transformer steels (i.e., electrical steel), e.g., Fe—Si alloys also rely on an austenite phase (γ-phase) to ferrite (α-phase) phase transformation during cooling to produce thin sheets having a desired “Goss” (cube-on-edge) texture. In contrast, in the embodiments described herein materials (e.g., Galfenol alloys) are used in which the ferrite phase does not transform during any stage of the process, i.e., remains constant.

The various embodiments provide a material with an eta (η)-fiber texture higher than has been previously unattainable. In one embodiment, the eta (η)-fiber texture is greater than about 45.3 area % up to about 80 area % or higher, such as up to about 100 area %, including any range therebetween. In one embodiment, the eta (η)-fiber texture is between about 45.4 area % and about 80 area %, such as between about 50 area % and about 80 area %.

The various embodiments also provide a material with a reduced fiber texture misorientation (as the term is defined herein) as compared to conventional materials. In one embodiment, the misorientation is less than about 20°, such as less than about 10°, such as less than about 5° or lower, such as no more than about 2°.

Magnetostriction is, in part, a function of fiber texture and misorientation. In one embodiment, and for a given amount of magnetic material performance enhancer, such as Gallium, the crystalline microstructures described herein have a substantially equivalent magnetostriction as compared to conventional single (or near-single) crystalline microstructures. It is also possible that in one embodiment, the crystalline microstructures described herein have an increased magnetostriction as compared to conventional single (or near-single) crystalline microstructures, such as greater than about 200 ppm up to about 300 ppm or higher, such as up to 350 ppm, or higher, such as 390 ppm or higher, such as about 399.9 ppm. In one embodiment, the magnetostriction is between about 200.1 ppm and about 300 ppm. In one embodiment, magnetostriction is at least about 200 ppm. In one embodiment, the single crystalline microstructure is an essentially perfect single crystal (i.e., defect free), and has a magnetostriction of 400.0 ppm.

The various embodiments provide for a material having a large grain diameter in the rolling direction (RD)-transverse direction (TD) plane. In one embodiment, the grain diameter is at least about 8 mm up to one to two orders of magnitude higher (such as at least about 800 mm or greater). In one embodiment, the grain diameter is between about 8.1 mm up and about 90 mm or higher, such as at least about 250 mm. In one embodiment, the grain diameter in the RD-TD plane is at least about 10 mm. Even larger grain diameters may be possible.

The various embodiments provide for a thin material, which, in one embodiment, have a thickness no more than about 0.118 in (3 mm). In one embodiment, the thickness is less than 0.110 in (2.8 mm) down to an order of magnitude smaller, such as less than about 0.08 in (0.02 mm), such as less than about 0.04 in (0.1 mm) such as about 0.01 in (0.254 mm) or smaller, including any range therebetween. In one embodiment, the material has a thickness of no more than about 0.015 in (0.381 mm). In one embodiment, the thickness is no more than about 0.006 in (0.17 mm). In one embodiment, the thickness ranges from about 0.005 in (0.127 mm) to about 0.015 in (0.381 mm).

The performance at frequency exhibited by the materials is dependent, in part, on the thickness of the material. The novel materials described herein exhibit a frequency from 10's of Hz up to one or two orders of magnitude higher (i.e., 100's of Hz, 1000's of Hz). In one embodiment, the operating frequency is at least about 1 kHz or higher, such as up to about 25 kHz or higher, such as up to about 30 kHz, including any range therebetween. In one embodiment, the frequency is greater than about 20 kHz. In one embodiment, the material has a thickness of no greater than about 0.38 mm and an operating frequency as high as about 10 kHz.

In one embodiment, the material has a thickness no greater than about 0.12 mm and an operating frequency as high as about 20 kHz or about 30 kHz. Higher frequencies may also obtainable, such as 50 kHz.

In one embodiment, the resulting materials are provided as sheets. In one embodiment, sheet sizes are large and limited only by the machine being used to form the sheet. In one embodiment, the sheet has an area of at least 1 in² (about 6.45 cm²) or between about 1 and about 19 in² (6.45 to 122.58 cm²), including any range therebetween. In one embodiment, the sheet has an area of at least 5 in² (32.36 cm²) or between about 5 in² (32.36 cm² and about 10 in² (64.52 cm²), including any range therebetween, or higher, such as about 15 in² (96.77 cm²) or higher, such as about 20 in² (129.03 cm²), including any area size therebetween. In some embodiments, the sheet has an area greater than about 20 in² (129.03 cm²), such as one or two magnitudes of order higher.

Various methods are used to make the materials described herein. However, particular steps are followed to ensure that the resulting material contains single crystalline or near-single crystalline magnetostrictive microstructures with the desired size and functionality.

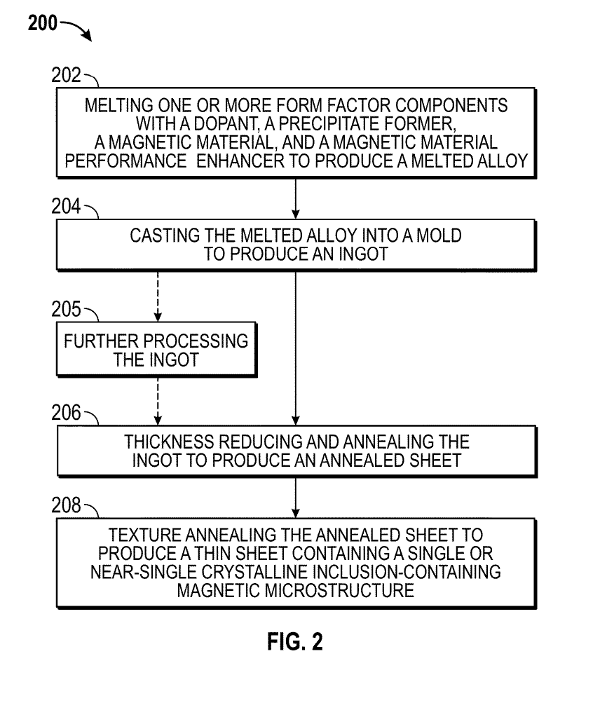

In the embodiment shown in FIG. 2, the method 200 comprises melting (e.g., induction melting) a form factor component together with components containing a precipitate former, a dopant, a magnetic material, and a magnetic material performance enhancer to produce a melted alloy 202; casting the melted alloy into a mold to produce an ingot 204, optionally further processing the ingot 205; thickness reducing and annealing the ingot to produce a thickness-reduced annealed sheet 206; and texture annealing the thickness-reduced annealed sheet to produce a thin sheet containing a single or near-single crystalline inclusion-containing magnetic microstructure. In one embodiment, more than one ingot can be made. In one embodiment, more than one thin sheet can be produced from one or more ingots.

In one embodiment, the melting is performed under a vacuum or partial vacuum, such as about 15 in Hg (0.5 atm).

In one embodiment, the form factor component comprises a piece of shim stock formed into a thin walled closed cylinder of a suitable length, which can be dependent on the application. In various embodiments the shim stock can be about 20 to about 25 cm in length, such as between about 23 and about 24 cm in length, including any range therebetween. In one embodiment, a shim stock having a length of about 23.5 cm is used. The form factor component bridges across the container into which the components are added (e.g., crucible) during the melting process and provides the melt with a small amount of carbon and tramp elements which improve the formability of the alloy, thus improving the rollability of the resulting sheet.

In one embodiment, the shim stock is carbon steel, such as, for example, a low carbon steel alloy containing less than about 400 ppmw C. In one embodiment, 1008 low carbon steel alloy is used as the form factor component. In one embodiment, 1018, 1020 or other low carbon steel alloys are used. In one embodiment 1008-1010 low carbon steel having a thickness of between about 0.01 in and about 0.31 in (0.025 to 0.79 cm) is used. In one embodiment, the thickness is about 0.01±.05 in (0.025±0.13 cm).

In one embodiment, iron is the magnetic material. In one embodiment, iron and carbon are added as an iron-carbon (Fe—C) master alloy, with the carbon improving formability of the resulting alloy, thus allowing it to be processed using convention metal working techniques. The carbon in the iron-carbon alloy also provides a carbon source (i.e., dopant) for carbide formation.

In one embodiment, electrolytic iron is also used. In one embodiment, high purity electrolytic iron (e.g., at least about 99.95% pure) is used as a “base” component to control the level of impurities in the alloy.

In one embodiment, the magnetic material enhancer is Gallium (Ga). Gallium can increase the magnetic performance of the magnetic material, e.g., iron. In one embodiment, the Ga has a 4N purity (99.99% pure). In one embodiment, Ga is added in a range of between about 0.1 wt % (0.08 at %) and about 24 wt % (20.2 at %), including any range therebetween, such as between about 20 wt % and about 24 wt %, such as between about 22 wt % and about 24 wt %, such as between about 22 wt % (18.4 at %) and about 23 wt % (19.3 at %), including any range therebetween. In one embodiment, the magnetic material performance enhancer is selected from Ga, aluminum (Al), Molybdenum (Mo), Germanium (Ge), Tin (Sn), Silicon (Si), Beryllium (Be) or a combination thereof.

Any suitable dopant can be used. In one embodiment, the dopant is carbon. In one embodiment, carbon is present in an iron-carbon alloy, such as in a range from about 1.5 up to about 3.5 wt % carbon in iron. As such, in one embodiment, carbon is added, either as part of an iron-carbon alloy, or separately, in a range of between about 1.5% to about 3.5% by weight (wt), such as between about 1.5 and about 3.0 wt %, such as between about 2.0 and about 2.5 wt %, including any range therebetween. In one embodiment, at least about 2.1 wt % carbon is added.

In one embodiment, carbon content is reduced (i.e., “diluted down”) when melted, to levels such as about 0.14 wt % (1400 parts per million by weight (ppmw), 0.68 at % C), or lower, such as down to 0.023 wt % (230 ppmw), including any range there between. In one embodiment, carbon loss is minimal, such as, for example, no greater than about 200 ppmw.

In one embodiment, the dopant can additionally or alternatively include nitrogen (N) and/or boron (B). Sulfur (S) may also be used as a dopant, if care is taken to prevent making the alloy brittle, thus rendering it unformable.

The various embodiments described herein utilize a plurality of inclusions to affect properties and characteristics of the final product. In one embodiment, the inclusions are useful for proper texture development during the texture annealing step of the process, i.e., during abnormal grain growth (AGG). The inclusion is formed when the dopant and a precipitate former combine. Any suitable precipitate former can be used. In one embodiment, an excess of precipitate former is added to provide a solid solution strengthening effect in the matrix, thus improving the mechanical robustness of the alloy.

In one embodiment, niobium (Nb) is used as the precipitate former. The amount of Nb used is determined by the targeted total inclusion content. In one embodiment, sufficient Nb is added so that the majority of the dopant is precipitated out, with excess Nb staying in solid solution. In one embodiment, the dopant is carbon which is precipitated as a carbide, and Nb is added in an amount no less than about 0.8 wt % (0.5 at % Nb).

Other precipitate formers may be used as long as the resulting inclusions are stable at the texture annealing temperatures and do not go into solution of the matrix. Such precipitate formers may include, for example, titanium (Ti), molybdenum (Mo), tungsten (W) and tantalum (Ta). Vanadium carbides, however, appear to not be stable at the texture annealing temperatures resulting in poor magnetostriction and no measurable AGG. (Testing with 38.3 wt % of 1008 low carbon steel (Earle M. Jorgensen Co., Lynwood, Calif.), 39.7 wt % electrolytic iron (99.95% min purity, Less Common Metals), 21.8 wt % gallium (99.99% min purity, Continental Metals), and 0.18 wt % vanadium metal (99.7% min purity, Alfa Aesar)).

The dopant and precipitate former concentrations can be varied, increased or decreased in any suitable manner. If too much dopant and precipitate former are used, too many inclusions can form, such that AGG does not occur, even at high texture annealing (i.e., dwell) temperatures. Rather, the inclusions can pin the small grains, such that they cannot gain a preferential size advantage.

While not wishing to be bound by this proposed theory, it is likely that during the texture annealing process, the presence of inclusions inhibits significant growth of any type of oriented grain (i.e. texture) as the temperature increases during heat treatment. In one embodiment, upon reaching the dwell temperature, no significant grain growth or texture development has yet occurred. After a specific incubation period (i.e. dwell time) eta (η)-fiber texture oriented grains can absorb significant thermal energy to overcome the pinning effects of the inclusions, while the non-eta (η) grains remain pinned. The grains which result in the resulting eta (η)-fiber texture can begin to grow rapidly after this incubation time and gain a large size advantage consuming the majority of the remaining matrix grains resulting in a single crystalline-like product, i.e., the Abnormal Grain Growth (AGG) response.

Various texture annealing parameters can be used. Dwell temperatures are selected to provide sufficient heat to cause a satisfactory AGG response and to provide sufficient thermal energy to allow eta (η)-fiber texture grains to overcome the pinning effects of the inclusions. In one embodiment, dwell temperatures can range from about 1100° C. to about 1250° C. It may be possible to use higher temperatures, as long as the AGG response is not negatively impacted, such as by causing non-ideal grains to become unpinned and grow in parallel to the eta (η)-fiber texture grains, thus reducing the magnitude of the AGG response. If the temperature is too low, the amount of thermal energy supplied is not sufficient to allow the eta (η)-fiber texture grains to overcome the pinning effects of the inclusions.

Sufficient dwell time is needed to allow AGG to occur. In one embodiment, the dwell time is less than about 12 hrs, such as less than about 6 hrs or lower, such as no more than about 2.5 hrs.

The dwell (annealing) temperature and dwell time are inversely related, such that a shorter dwell time can be used with a higher dwell temperature. Any suitable dwell temperature can be used. In one embodiment, the dwell temperature is between about 1100° C. and about 1250° C.

Any suitable heating and cooling rate can be used. In one embodiment, the heat and cooling rate can vary from about 1° C./min to about 10° C./min.

Any suitable atmospheric or combination of environments can be used during the texture annealing step. In one embodiment, an inert environment is used, such as argon or helium. In one embodiment, the environment additionally (at a different point in the process) or alternatively comprise 100% dry hydrogen (H₂). In one embodiment, the environment can additionally or alternative comprise 50% dry H₂/50% Nitrogen, N₂ mix.

In one embodiment, the dwell temperature does not exceed 1250° C. and the dwell time is less than about 6 hrs, such as about 2.5 hrs in an argon environment.

In one embodiment, texture annealing in a 100% dry H₂ environment produces a microstructure having fewer residual matrix grains, i.e., islands. In one embodiment, microstructure analysis of a material created in such an environment has approximately 33.3% fewer residual matrix grains as compared to a material produced in an argon environment. In one embodiment, the 100% dry H₂ environment can produce a sharper overall eta (η)-fiber texture with misalignment with the RD which is about 33% lower, on average, than the overall eta (η)-fiber texture of a material prepared in an argon environment. In one embodiment, the overall eta (η)-fiber texture is no more than about 13° misalignment with the RD, on average, as compared to an approximately of at least about 18° misalignment with the RD, on average, for an argon environment.

A reduced eta (η) misorientation and increased area % eta (η)-fiber texture contributes to an improved magnetostrictive performance. In one embodiment, the magnetic material performance enhancer is Gallium and the environment during texture annealing is a 100% dry H₂ environment, with the material demonstrating a saturation magneostriction at least 8% higher, such as about 9% higher, or more, on average, than the saturation magnetostriction of a material prepared in an argon environment. In one embodiment, the saturation magneostriction, on average, is at least about 252 ppm, on average, as compared to a saturation magneostriction no more than about 231 ppm, on average, for an argon environment. However, in one embodiment, the use of argon, in combination with the other features discussed herein, results in an improved product as compared to the processes of the prior art.

In one embodiment, the AGG is moderate or strong, and is dependent on the level of added dopant, such as carbon. In one embodiment, no more than about 230 ppm C (0.1 at %) is present and the resulting AGG is weak. In one embodiment, between about 230 and about 1400 ppmw of C (0.1 to 0.68 at %) is present with the resulting AGG being moderate to strong. In one embodiment, carbon is added in a range of between about 700 ppmw (0.34 at %) and about 1000 ppmw (0.5 at %), with the resulting AGG being moderate to strong. Embodiments utilizing a larger carbon content may have residual matrix grains remaining after texture annealing which could have a negative impact on magnetic properties such as magnetostriction.

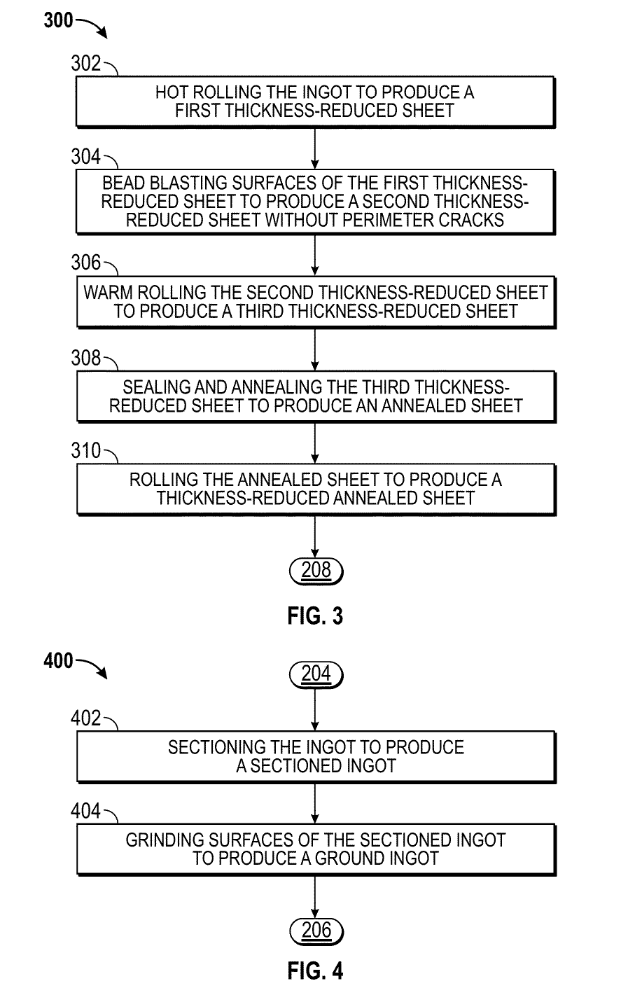

In one embodiment, as shown in FIG. 3, the thickness reducing step 206 comprises first hot rolling the ingot to produce a first thickness-reduced sheet 302; bead blasting a surface of the sheet to produce a second thickness-reduced sheet without perimeter cracks 304; warm rolling the second thickness-reduced sheet to produce a third thickness-reduced sheet 306, sealing and annealing the third thickness-reduced sheet to produce annealed sheets 308 and rolling the annealed sheets to produce a thickness-reduced annealed sheet 310 (cold rolling), the product of which is provided to the texture annealing step 208 described in FIG. 2. Again, in one embodiment, more than one ingot and/or more than one sheet of any of the aforementioned types can be produced.

In one embodiment, the hot rolling step is an optional cross-rolling step which can be performed to increase sheet width (90° rotation). The sealing and annealing step (308) is useful for reducing or eliminating internal stresses prior to the cold rolling step (310). The sealing and annealing step (308) can be performed in any suitable container, such as a stainless steel bag. Any suitable temperature and time can be used in this step. The rolling step 310 can be performed using a combination of lubricants and stack rolling

In one embodiment, as shown in FIG. 4, the optional further processing of the ingot step 205 includes sectioning the ingot produced in the casting step 204 of FIG. 2, to produce a sectioned ingot 402 and grinding a surface of the sectioned ingot to produce a ground ingot 404 which is provided to the thickness reducing step or steps of 206 as shown in FIGS. 1 and 2. Again, in one embodiment, more than one ingot and/or more than one sheet of any of the aforementioned types can be produced.

In one embodiment, the casting is sectioned into smaller sections as a result of size limitations in the furnace being used. In one embodiment, no sectioning is performed and the entire casting is rolled in one piece.

In one embodiment, a composition is provided having a composition formula of (Fe—Ga—Al—Mo—Ge—Sn—Si—Be)ₐ(Nb_{d}—Ti_{d}—Mo_{d}—Ta_{d}—W_{d})_{b}(C—N—B—S)_{c} wherein a≧98, b≦1, c≦1 and d≦2, such as d=1 or 2, wherein a+b+c=100. In one embodiment, a composition is provided having a composition of (Fe—Ga)₉₉(Nb)_{0.5}(C)_{0.5}.

The resulting materials are useful in a variety of devices, including, for example, transducers, actuators, energy harvesters, and the like. In one embodiment, the resulting material is integrated into a medical hand piece tool with the magnetostriction providing the motion to actuate a cutting blade to remove tissue and cut through bone. In one embodiment the resulting material is integrated into an energy harvesting device coupled to a vibrating motor. The motor vibrations induce magnetization changes in the resulting material generating a voltage in a coil coupled to the resulting material resulting in current flow for storage in a battery or capacitor or direct use in a sensor or light.

Embodiments of the invention will be further described by reference to the following examples, which are offered to further illustrate various embodiments of the present invention. It should be understood, however, that many variations and modifications may be made while remaining within the scope of the various embodiments described herein.

### Example 1

### 803 ppmw C, 50 H₂/50 N₂ Environment

### Starting Materials

0.8 wt % of 1008 low carbon steel (Earle M. Jorgensen Co., Lynwood, Calif.), 72.6 wt % electrolytic iron (99.95% min purity, Less Common Metals, Birkenhead, England), 21.5 wt % gallium (99.99% min purity, Continental Metals, Union City, Calif.), 4.3 wt % iron-carbon master alloy containing 2.4 wt % carbon (Ames Laboratory, Ames, Iowa) and 0.8 wt % niobium (Nb) metal (99.8% min purity, Alfa Aesar, Ward Hill, Mass.) were combined in a crucible. The Galfenol alloy system has a melt temperature of approximately 1450° C.

The contents were melted using an MK11 Induction Melting System (Pillar Induction, Brookfield, Wis.) to a maximum temperature of about 1587° C. The pour temperature was about 1560° C.

The melted contents were cast in a steel mold having a size of approximately 1.45 in ×0.6 in ×12 in (36.83 mm×15.24 mm×304.8 mm) to produce an ingot, after which the chemical make-up of the ingot was determined.

The ingot was hot rolled under argon cover gas (to minimize reaction) using an International Rolling Mills (IRM) Model 2050 5×8 Hot Lab Rolling Mill (with rollers having 5 in (127 mm) diam and 8 in (203.2 mm) length, and 7.5 HP motor, International Rolling Mills, Pawtucket, R.I.) at 900° C. with a 30 minute pre-heat, followed by 5 minute re-heat per pass. Prior to entering the roller, the ingot had an initial thickness of 0.610 in (15.494 mm), and thereafter exhibited a 25% reduction per pass. After 12 passes, the final thickness was 0.049 in (1.245 mm).

The resulting sheet was then warm rolled under argon gas in the IRM mill at 300° C. with a 15 minute pre-heat followed by 2-3 minute reheat per every two passes. After the first pass, the resulting sheet had a thickness of 0.049 in (1.245 mm), and thereafter exhibited a 0.002 in (0.051 mm) reduction per pass. After 33 passes, the final thickness was 0.023 in (0.584 mm).

Each sheet was sealed in a stainless steel bag back-filled with argon gas and subjected to an intermediate anneal in a furnace with a flowing argon environment at 850° C. for about 1 hour.

Thereafter, each sheet was cold rolled in the IRM mill at room temperature (RT). After the first pass, the resulting sheet had a thickness of 0.023 in (0.584 mm), and thereafter exhibited a 0.001 in (0.025 mm) reduction per pass. After 38 passes, the final thickness was 0.015 in (0.381 mm). As such, the total thickness reduction from the initial thickness of 0.610 in (15.494 mm) was 97.5% and the final sheet size was about 1.75 in (width) (44.45 mm) by about 12 in (length) (304.8 mm).

A subsequent heat treat/texture annealing process was performed at an outside facility in a batch furnace under a relatively complex heat treat cycle comprising a dwell time of 5 min. at 800° C., in a wet hydrogen atmosphere, 50° F. dewpoint. The sheet was then was force air-cooled to RT using a fan and was then heated from RT to 950° C. at 35° C./minute; then to 1175° C. at 1° C./minute with a dwell time of 12 hours in 50% dry H₂/50% N₂ gas mix.

### Characterization Methods

### Macrostructure

Each texture-annealed sheet was analyzed macroscopically to determine the extent of abnormal grain growth AGG, grain characteristics, and fiber texture. FIG. 6 shows a macroscopic image of a portion of a texture annealed sheet produced under the stated conditions, with the locations of test samples (solid lines) indicated for SEM/EBSD and magnetostriction, respectively. As shown in FIG. 6 (scale marker: mm), close to 100% of the entire sheet which as approximately 9.5 in ×1.5 in (241.3 mm×38.1 mm) is one grain (approximately 14 in²) (90.322 cm²) with 3 smaller grains, A,B,C, outlined as shown.

### Chemical Composition

Chemical analysis was performed to determine the composition of the ingots as noted above. Specifically, a combustion analysis technique was used to determine the carbon content using a LECO Model CS-444LS device (LECO Corp., St. Joseph, Mich.). Glow discharge mass spectroscopy (GDMS) was used to determine the Nb content using a Vacuum Generators, Model VG9000 device (Newburyport, Mass.), and Ga content was determined using inductively coupled plasma mass spectroscopy (ICP-MS) using a Vacuum Generators Model PQ3 unit. See, for example, http://northernanalytical.com/techniques.htm), Northern Analytical Laboratory, Inc., which is hereby incorporated herein by reference. The chemical make-up and stoichiometry of the inclusions was determined using a JEOL JXA—8200 Electron Microprobe System (Peabody, Mass.) with five wavelength dispersive spectrometers (WDS). The total amounts are shown in Table 1.

TABLE 1
Chemical Make-Up (Partial) of Cast Ingot M1-9-64

| Element | Value | | Method |
|---|---|---|---|
| C | 803 | ppmw | LECO |
| Nb | 9000 | ppmw | GDMS |
| Ga | 21.7 | wt % | ICP-MS |

### Texture and Microstructure

Each sheet was also examined microstructurally using SEM/EBSD to assess grain characteristics and fiber texture. Specifically, an Electron Backscatter Diffraction (EBSD) analysis was conducted on each sheet in order to quantify the microstructure and texture through the use of Orientation Imaging Maps and Pole Figure measurements. The EBSD analysis technique was performed utilizing a Carl Zeiss Evo 50 Scanning Electron Microscope (SEM) (Carl Zeiss Microscopy LLC, Thornwood, N.Y.), an Oxford Instruments Nordlys Electron Back-Scattered Pattern (EBSP) detector, and HKL Channel 5 Orientation Imaging Microscopy (OIM) acquisition software (Oxford Instruments, Tubney Woods, Abingdon, Oxfordshire, UK). The SEM accelerating voltages were 15-20 kV SEM, a typical step size was 35 μm, and the scanned areas were 12 mm×10 mm.

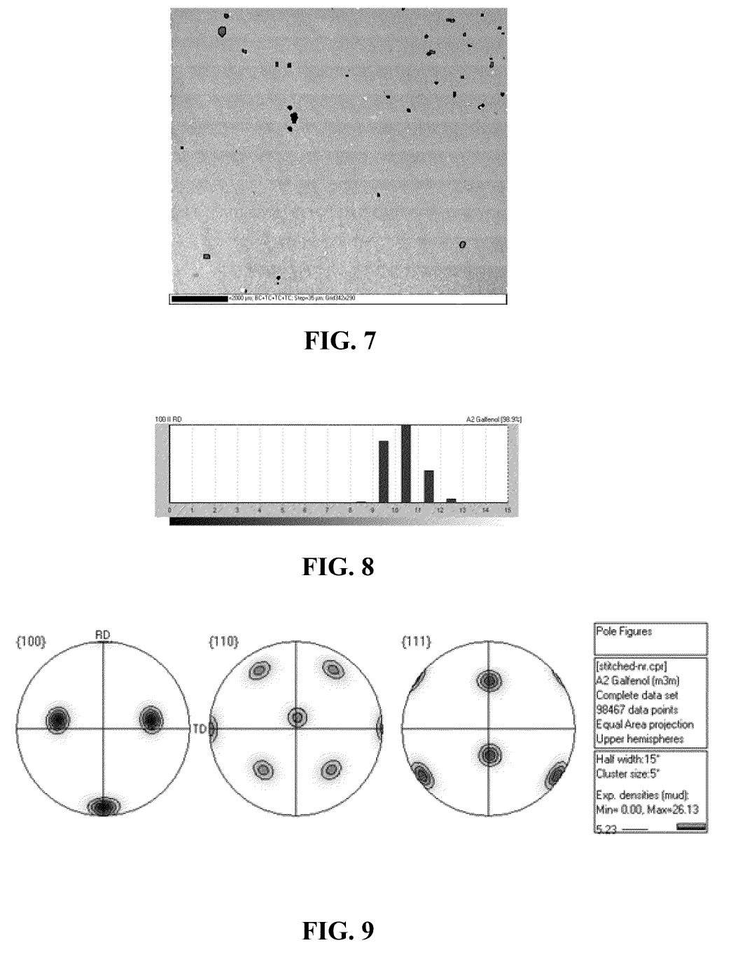

FIG. 7 (200×) shows an SEM/EBSD image of the magnetostriction sample area indicated in FIG. 6. Area fraction analysis of the eta (η)-fiber oriented grains showed that the single crystal comprised a 99 area %, with a minor amount of island grains present. FIG. 8 is a histogram showing the 9-13° misorientation in this sample.

FIG. 9 shows the pole figure analysis for this sample. As can be seen there is an extremely strong {100} texture parallel to the RD, Max MUD=26.13. This texture is part of the desired eta (η)-fiber texture.

### Magnetostriction

Numerous samples from the heat treated sheets were tested using an electro-magnet and stepper motor apparatus which generates a 2 Tesla magnetic field across a 50 mm gap. A typical sample size was 15 mm×10 mm with the 15 mm direction parallel to the RD of the sample.

Each sheet sample was fitted with a Vishay CEA-06-250UN-350 strain gauge parallel to the RD and placed in the magnetic field where it was rotated within the plane of the sheet via the stepper motor through 400 degrees of rotation.

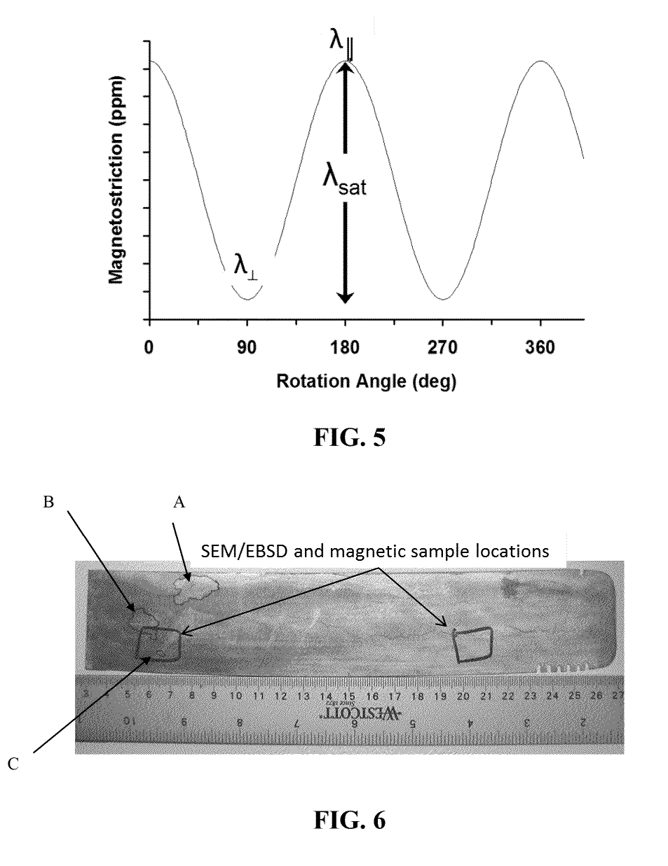

Testing yielded a cosine plot of magnetostriction versus rotation angle in which the saturation magnetostriction value (λₛₐₜ) is assumed to be the difference between the peak value (λ_{∥}), at 0° or 180°, and trough value (λ_{⊥}), at 90° or 270°; λₛₐₜ=λ_{∥}−λ_{⊥}. FIG. 5 is a generic representation of the type of graph which can be produced with this type of characterization.

The saturation magneostriction for this sample was measured as 284 ppm for with a misorientation of between about 9 and 13° (See FIG. 8). The resultant large magnetostriction value is evidence that a single crystalline or near-single crystalline microstructure with strong eta (η)-fiber orientation (or lack of misorientation with respect to the RD) is desired for applications utilizing this material system.

### Example 2

### 621 ppmw C, Argon Environment

### Starting Materials

0.5 wt % of 1008 low carbon steel (Earle M. Jorgensen Co., Lynwood, Calif.), 71.7 wt % electrolytic iron (99.95% min purity, Less Common Metals), 22.7 wt % gallium (99.99% min purity, Continental Metals), 4.3 wt % iron-carbon master alloy containing 4.3 wt % carbon (Ames Laboratory) and 0.8 wt % Nb metal (99.8% min purity, Alfa Aesar) were combined in a crucible. The Galfenol alloy system has a melt temperature of approximately 1450° C.

The contents were melted using the MK11 Induction Melting System to a maximum temperature of about 1581° C. The pour temperature was about 1560° C.

The melted contents were cast into the same-size steel mold as in Example 1. Chemical analysis was performed to determine the C and Nb content as described in Example 1. (Galfenol was not measured in this instance, but was likely in the range of about 20 to about 22 wt %). The total amounts are shown in Table 2.

TABLE 2
Chemical Make-Up (Partial) of Cast Ingot M1-9-64

| Element | Value (ppmw) | Method |
|---|---|---|
| C | 621 | LECO |
| Nb | 6668 | GDMS |

The contents were hot rolled under argon cover gas (to minimize reaction) using the IRM rolling mill described in Example 1, at 900° C. with a 30 minute pre-heat, followed by 5 minute re-heat per pass. Prior to entering the roller, the ingot had an initial thickness of 0.603 in (15.316 mm), and thereafter exhibited a 25% reduction per pass. After 12 passes, the final thickness was 0.046 in (1.168 mm).

The resulting sheet was then warm rolled under argon gas in the IRM mill at 300° C. with a 15 minute pre-heat followed by 2-3 minute reheat per every two passes. After the first pass, the resulting sheet had a thickness of 0.046 in (1.168 mm), and thereafter exhibited a 0.002 in (0.0508 mm) reduction per pass. After 26 passes, the final thickness was 0.023 in (0.584 mm).

Each sheet was sealed in a stainless steel bag back-filled with argon gas and subjected to an intermediate anneal in a furnace with a flowing argon environment at 850° C. for about 1 hour.

Thereafter, each sheet was cold rolled in the IRM mill at room temperature (RT). After the first pass, the resulting sheet had a thickness of 0.023 in (0.584 mm), and thereafter exhibited a 0.001 in (0.025 mm) reduction per pass. After 38 passes, the final thickness was 0.014 in (0.356 mm). As such, the total thickness reduction from the initial thickness of 0.603 in (15.316 mm) was 97.7% and the final sheet size was about 1.75 in (width) (44.45 mm) by about 12 in (length) (304.8 mm).

A subsequent heat treat/texture annealing process was performed in-house with a Carbolite® Model CTF 12/65/550 tube furnace (Hope Valley, England). A flowing argon gas environment was maintained throughout the annealing process with each sheet heated from RT to 850° C. at 10° C./minute; then to 1175° C. at 10° C./minute with a dwell time of 12 hours.

### Characterization and Results

The samples were characterized as described in Example 1.

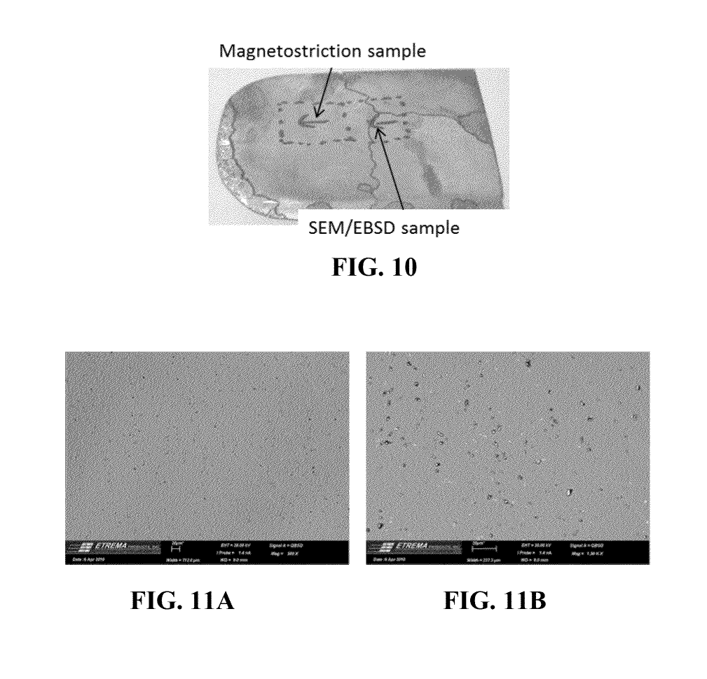

FIG. 10 shows the macroscopic image of a portion of the texture annealed sheet produced, with the locations of test samples (dashed lines) indicated for magnetostriction and texture (SEM/EBSD) analysis, respectively. FIGS. 11A (500×) and 11B (1500×) show SEM images of the magneostriction sample area. Analysis of the captured image using ImageJ 1.44p software, NIH, USA showed the area % of carbides to be 2.4%.

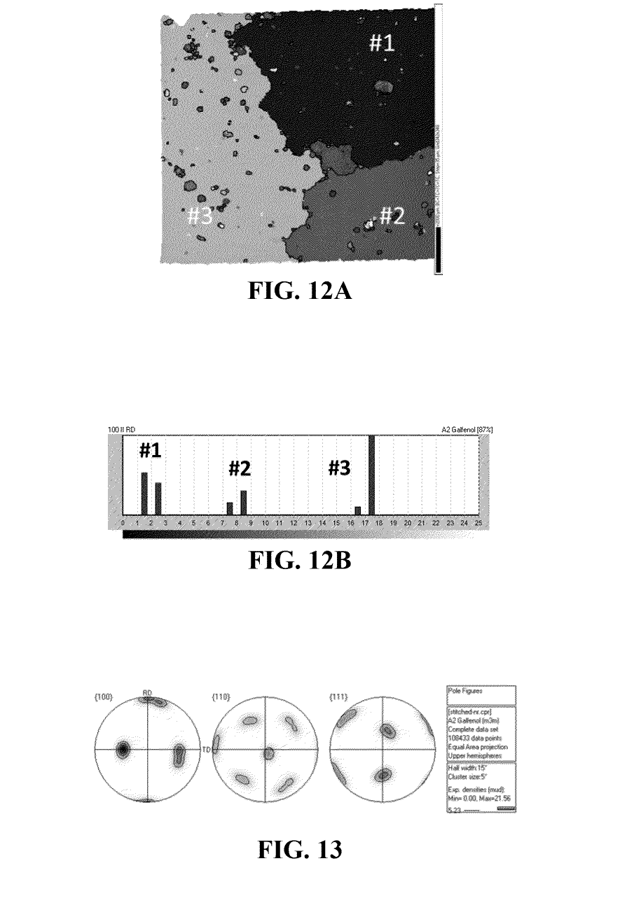

FIG. 12A shows an EBSD orientation imaging map of the grains in the magnetostriction sample area with the numbering “#1”, “#2,” and “#3” showing three different grain areas. Analysis of the captured image shows that the three crystals comprise an 87% area, with a minor amount of island grains present. FIG. 12B is a histogram showing misorientation for the three grains, with 18° being the maximum misorientation measured. FIG. 13 shows the pole figure analysis for this sample. As can be seen there is an extremely strong {100} texture parallel to the RD, Max MUD=21.56. This texture is part of the desired eta (η)-fiber texture.

The saturation magneostriction was measured on a sample taken from grain #3 (which had a misorientation angle of 18°) as 225 ppm.

### Example 3

### 621 ppmw C, 100% Dry H2 Environment

The same materials as described in Example 2 were processed in the same manner as in Example 2 up to the texture annealing cycle.

In this example, the heat treatment/texture annealing process was performed at an outside laboratory using a tube furnace. A flowing 100% dry H₂ environment was maintained throughout the annealing process with each sheet heated from RT to 850° C. at 10° C./minute, and then heated to a temperature of about 1250° C. at a rate of about 1° C./minute, with a dwell time of approximately 12 hours.

### Characterization and Results

The samples were characterized as in the previous examples.

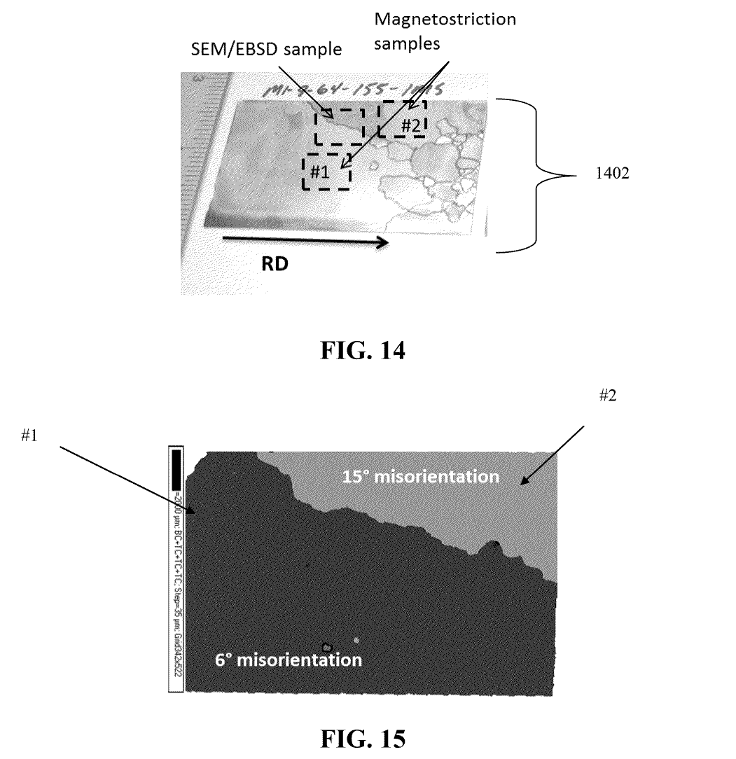

FIG. 14 shows the macroscopic image of a portion of the texture annealed sheet produced, with the locations of test samples (dashed lines) indicated for magnetostriction and texture (SEM/EBSD) analysis, respectively. As FIG. 14 (scale marker: inches) shows, this sample exhibited a large AGG response, as indicated by the multiple grain boundary outlines in area 1402 as indicated.

FIG. 15 shows an EBSD orientation imaging map of areas #1 and #2 (FIG. 14) showing two grains encompassing essentially all of the eta (η)-fiber texture. The misorientation angle for #1 is within 6° and the misorientation angle for #2 is within 15 degrees (°). As such, both grains are oriented to within 15° (93 area %).

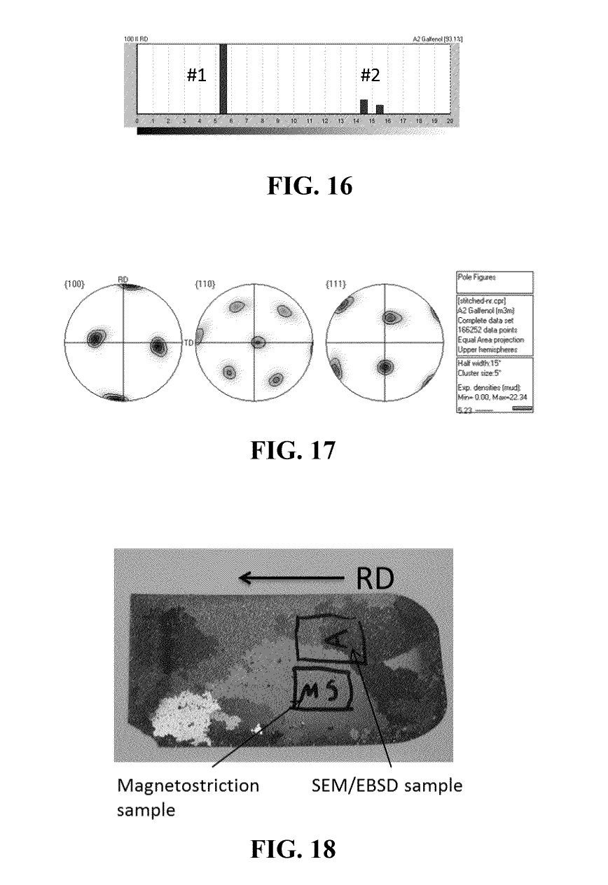

FIG. 16 is a histogram showing the 6 and 15° misorientation angles between the eta (η)-fiber texture and the RD for the two grains.

FIG. 17 shows a pole figure analysis for this sample. As can be seen there is an extremely strong {100} texture parallel to the RD, Max MUD=22.34. This texture is part of the desired eta (η)-fiber texture.

The saturation magnetostriction was measured as 225 ppm for this sample (having a 6° misorientation angle). These results support the theory that a strong eta (η)-fiber texture is necessary to achieve large magnetostrictions in this material system.

### Example 4

### 1402 ppmw C, Argon Environment

1.1 wt % Nb metal (99.8% min purity, Alfa Aesar, Ward Hill, Mass.) 3.0 wt % of 1008 low carbon steel (Earle M. Jorgensen Co., Lynwood, Calif.),), 67.9 wt % electrolytic iron (99.95% min purity, Less Common Metals), 21.6 wt % gallium (99.99% min purity, Continental Metals), 6.4 wt % iron-carbon master alloy containing 2.2 wt % carbon (Ames Laboratory) and 1.1 wt % Nb metal (99.8% min purity, Alfa Aesar) were combined in a crucible. The Galfenol alloy system has a melt temperature of approximately 1450° C.

The contents were melted using the MK11 Induction Melting System to a maximum temperature of about 1600° C. The pour temperature was about 1555° C.

The melted contents were cast into the steel mold described in Example 1. Chemical analysis as described in Example 1 to determine the C content, at 1402 ppmw. In order to maintain a minimum 1:1 atomic ratio with carbon, Nb levels were likely between about 1 and 1.3 wt %. Ga levels were likely between about 20 and about 22 wt %

The contents were hot rolled under argon cover gas (to minimize reaction) using the IRM rolling mill described in Example 1, at 900° C. with a 30 minute pre-heat, followed by 5 minute re-heat per pass. Prior to entering the roller, the ingot had an initial thickness of 0.603 in (15.316 mm), and thereafter exhibited a 25% reduction per pass. After 12 passes, the final thickness was 0.044 in 1.118 mm).

The resulting sheet was then warm rolled under argon gas in the IRM mill at 300° C. with a 15 minute pre-heat followed by 2-3 minute reheat per every two passes. After the first pass, the resulting sheet had a thickness of 0.044 in (1.118 mm), and thereafter exhibited a 0.002 in (0.051 mm) reduction per pass. After 30 passes, the final thickness was 0.020 in (0.508 mm).

Each sheet was sealed in a stainless steel bag back-filled with argon gas and subjected to an intermediate anneal in a furnace with a flowing argon environment at 850° C. for about 1 hour.

Thereafter, each sheet was cold rolled in the IRM mill at room temperature (RT). After the first pass, the resulting sheet had a thickness of 0.020 in (0.508 mm), and thereafter exhibited a 0.001 in (0.025 mm) reduction per pass. After 18 passes, the final thickness was 0.015 in (0.381 mm). As such, the total thickness reduction from the initial thickness of 0.603 in (15.316 mm) was 97.7% and the final sheet size was about 1.75 in (width) (44.45 mm) by about 12 in (length) (304.8 mm).

A subsequent heat treat/texture annealing process was performed with the in-house Carbolite® tube furnace. A flowing argon gas environment was maintained throughout the annealing process with each sheet heated from RT to 1185° C. at 10° C./minute with a dwell time of 12 hours.

### Characterization and Results

The samples were characterized as in the previous examples.

FIG. 18 shows the macroscopic image of a portion of the texture annealed sheet. This sample exhibited a large AGG response, as indicated by the grain boundary outlines. The RD is indicated by the arrow, while locations of test samples (solid lines) are indicated for magnetostriction (“M”) and SEM/EBSD (“A).

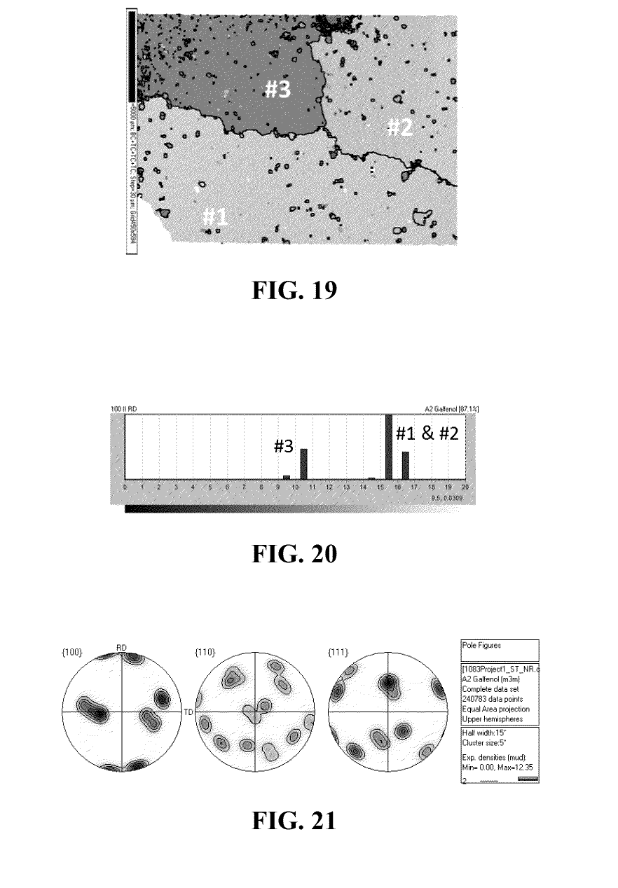

FIG. 19 shows an EBSD orientation imaging map of the grains in the magnetostriction sample area, with the numbering “#1”, “#2,” and “#3” showing three different grain areas according to various embodiments. The three grains encompassed essentially all of the eta (η)-fiber texture.

FIG. 20 is a histogram showing the misorientation for the three grains. As can be seen, all grains were oriented to within 20° (87.1 area %).

FIG. 21 shows a pole figure analysis for the three grains. As can be seen, there is an extremely strong {100} texture parallel to the RD, Max MUD=12.35. This texture is part of the desired eta (η)-fiber texture. However, this MUD value is weaker than the other experiments due to the large number of island grains present, as seen in FIG. 19. This result confirms the hypothesis that too much carbon can increase the number of islands remaining after texture annealing.

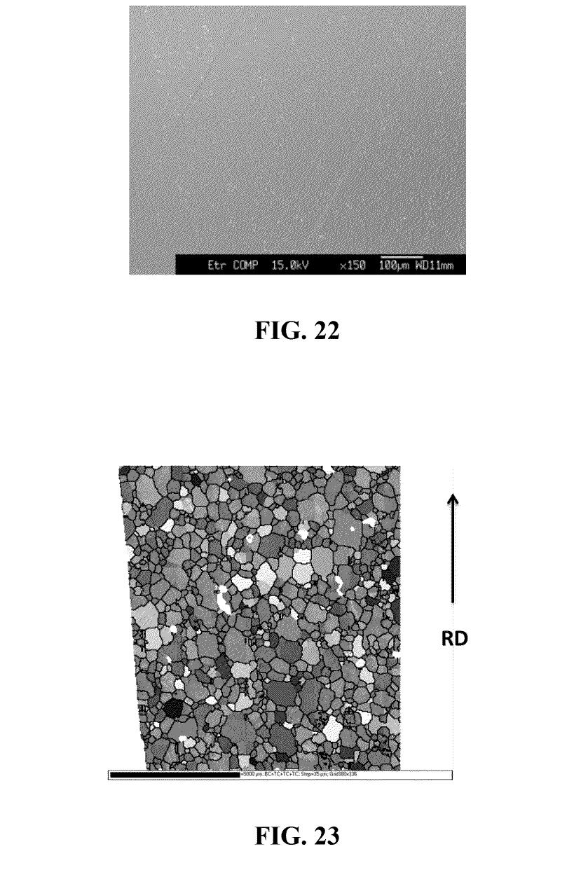

FIG. 22 (150×) shows an SEM image from a microprobe analysis using the JEOL Microprobe of the SEM/EBSD sample area of FIG. 19. As can be seen, there are a significant number of inclusions (bright spots) present in the texture annealed sheet. The chemical make-up of the inclusions as determined by the microprobe analysis, indicated a 2:1 Nb:C ratio, which is suggestive of a Nb₂C particle.

The saturation magnetostriction was measured as 245 ppm for the sample taken from grain #1 (having a 16° misorientation angle).

The large magnetostriction result is expected due to the strong eta (η)-fiber texture formed with a low misorientation angle.

### Example 5

### No Inclusions/Particles, Argon Environment

### Starting Materials

Thirty-nine (39) wt % of 1008 low carbon steel (Earle M. Jorgensen Co., Lynwood, Calif.), 39 wt % electrolytic iron (99.95% min purity, Less Common Metals) and 22 wt % gallium (99.99% min purity, Continental Metals) were combined in a crucible. Of note, no precipitate former, such as Nb, was used.

The contents were melted using the MK11 Induction Melting System to a maximum temperature of about 1570° C. The pour temperature was 1560° C.

The melted contents were cast into the same-size steel mold as in Example 1. Carbon content from the 1008 low carbon steel was minimal and likely at less than about 250 ppmw. Ga levels were likely between about 20 and 22 wt %, as Ga losses were minimal during processing. Of note, with no precipitate former, no inclusions were formed.

The contents were hot rolled under argon cover gas using the IRM rolling mill described in Example 1, at 900° C. with a 30 minute pre-heat, followed by 5 minute re-heat per pass. After the first pass, the resulting sheet had a thickness of 0.593 in (15.062 mm), and thereafter exhibited a 25% reduction per pass. After 13 passes, the final thickness was 0.047 in (1.194 mm).

The resulting sheet was then warm rolled under argon gas in the IRM mill at 300° C. with a 15 minute pre-heat followed by 2-3 minute reheat per every two passes. After the first pass, the resulting sheet had a thickness of 0.047 in (1.194 mm), and thereafter exhibited a 0.002 in (0.051 mm) reduction per pass. After 52 passes, the final thickness was 0.022 in (0.559 mm).

Each sheet was sealed in a stainless steel bag back-filled with argon gas and subjected to an intermediate anneal in a furnace with a flowing argon environment at 850° C. for about 1 hour.

Thereafter, each sheet was cold rolled in the IRM mill at room temperature (RT). After the first pass, the resulting sheet had a thickness of 0.022 in (0.559 mm), and thereafter exhibited a 0.001 in (0.025 mm) reduction per pass. After 38 passes, the final thickness was 0.014 in (0.356 mm). As such, the total thickness reduction from the initial thickness of 0.593 in (15.062 mm) was 97.7% and the final sheet size was about 1.75 in (width) (44.45 mm) by about 12 in (length) (304.8 mm).

A subsequent heat treat/texture annealing process was performed with the in-house Carbolite® tube furnace. A flowing argon gas environment was maintained throughout the annealing process with each sheet heated from RT to 1100° C. at 10° C./minute with a dwell time of 24 hours.

FIG. 23 is a texture analysis (SEM/EBSD) of the texture annealed sheet. As can be seen in FIG. 23, without the presence of the inclusion, there is a lack of AGG, with a small average grain size of ˜340 μm.

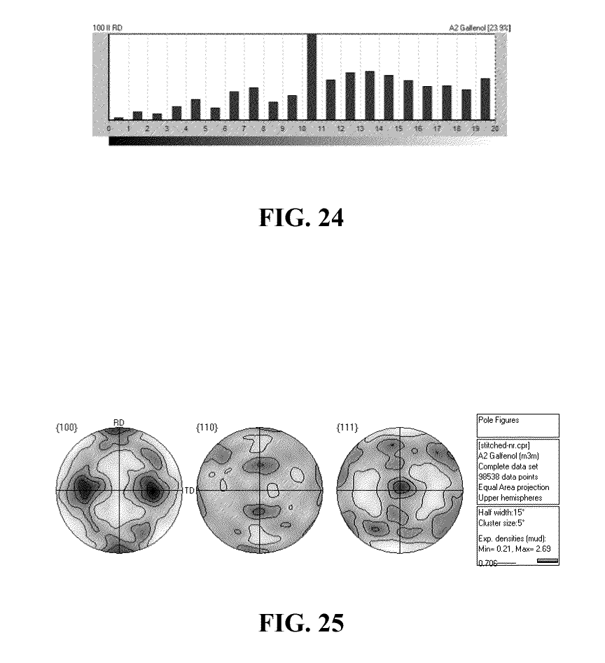

FIG. 24 is a histogram showing the misorientation for the grains shown in FIG. 23. As can be seen, the various eta (η)-fiber texture oriented grains present have no strong preferred orientation. Furthermore, the total area % of the sample with an eta (η)-fiber texture misorientation was only 23.9%, far short of the typical 80+% observed in AGG samples.

FIG. 25 shows a pole figure analysis for the grains shown in FIG. 23. As can be seen, the pole figure analysis shows a weak {100} texture parallel to the RD with a Max MUD of 2.69. The weak texture is part of the desired eta (η)-fiber texture. The MUD value is weak due to no abnormal grain growth (AGG), which is a result of the lack of carbides (inclusions) in the sample.

Five samples were excised from the texture annealed sheet for magnetostriction characterization. The average measured magnetostriction was 117 ppm, with a range from 94-136 ppm. The poor magnetostriction values are a result of the weak crystallographic texture developed during processing, which again demonstrates the poor results which occur in the absence of an inclusion such as carbides.

The various embodiments provide for microstructures, methods and devices not previously attainable in the art. In one embodiment, a product is provided, comprising a single or near-single crystalline inclusion-containing magnetic microstructure, such as, for example, a Galfenol-carbide microstructure. In one embodiment, the product comprises one or more thin sheets. In various embodiments, an inclusion in the inclusion-containing magnetic microstructure is niobium carbide, which can include an amount of Nb₂C.

The product can possess various features including, but not limited to, an eta (η)-fiber texture greater than about 45.3 area % up to about 100 area % and a misorientation of less than about 30 degrees; and/or a magnetostriction between about 200.1 ppm and about 400 ppm; and/or a grain diameter in the rolling direction (RD)-transverse direction (TD) plane of at least about 10 mm; and/or a thickness of no more than about 3 mm, such as no more than about 0.381 mm; and/or an operating frequency from about DC to about 30 kHz; and/or between about 230 and about 1400 ppmw of C (0.1 to 0.68 at %) and a moderate to strong AGG. In one embodiment, the AGG is weak. In one embodiment, the product can comprise (Fe—Ga)₉₉(Nb)_{0.5}(C)_{0.5}.

The product can be configured for or adapted for use in a device, such as an actuator, sensor or energy harvester. In one embodiment, the energy harvester is a motor mount configured to convert motor vibrations from a motor into electrical energy.

In one embodiment, a method is provided comprising making one or more thin sheets comprising combining one or more form factor components (e.g., shim stock formed into a thin walled closed cylinder) with a dopant (e.g., carbon (C), nitrogen (N), boron (B), sulfur (S) or a combination thereof), a magnetic material (E.g., iron), a magnetic material performance enhancer (e.g., Gallium (Ga), Aluminum (Al), Molybdenum (Mo), Germanium (Ge), Tin (Sn), Silicon (Si), Beryllium (Be) or a combination thereof) and a precipitate former (e.g., titanium (Ti), molybdenum (Mo), tungsten (W), tantalum (Ta) or a combination thereof) to produce a melted alloy; casting the melted alloy into a mold to produce at least one ingot; optionally further processing the at least one ingot; thickness reducing and annealing the at least one ingot to produce one or more annealed sheets; and texture annealing the one or more annealed sheets to produce abnormal grain growth (AGG) in the one or more thin sheets, each of the one or more thin sheets containing a single or near-single crystalline inclusion-containing magnetic microstructure (e.g., a Galfenol-carbide microstructure).

In one embodiment, the method described above further includes adding carbon (such as in an Fe—C alloy) in a range of between 1.5 wt % and 3.5 wt % and/or performing the texture annealing at a dwell temperature from about 1100° C. to about 1250° C. and/or a dwell time of less than about 12 hrs and/or wherein the magnetic material performance enhancer is Gallium added in a range of between about 0.1 wt % (0.08 at %) and about 24 wt % (20.2 at %) and/or wherein the texture annealing is performed in an environment selected from hydrogen, hydrogen and nitrogen, argon, or a combination thereof.

In one embodiment, a product is provided, made according to any one or all of the methods described herein.

In one embodiment, a method of increasing performance of one or more magnetic thin sheets is provided comprising melting one or more form factor components, a dopant, a magnetic material performance enhancer and a precipitate former to a magnetic material to produce a melted alloy; casting the melted alloy into a mold to produce one or more ingots; optionally further processing the one or more ingots; thickness reducing and annealing the one or more ingots to produce one or more annealed sheets; and texture annealing the one or more annealed sheets to produce the one or more magnetic thin sheets, each containing a single or near-single crystalline inclusion-containing magnetic microstructure. In one embodiment, the melting is induction melting performed under a vacuum or partial vacuum.

In one embodiment, a composition is provided comprising a magnetic microstructure having a composition formula of: (Fe—Ga—Al—Mo—Ge—Sn—Si—Be)ₐ(Nb_{d}—Ti_{d}—Mo_{d}—Ta_{d}—W_{d})_{b}(C—N—B—S)_{c} wherein a≧98, b≦1, c≦1, d≦2 and a+b+c=100. In one embodiment, d=1 or 2. In one embodiment, the composition comprises (Fe—Ga)₉₉(Nb)_{0.5}(C)_{0.5}.

In one embodiment, a device is provided comprising a housing; and one or more thin sheets contained within the housing, each of the one or more thin sheets containing a single or near-single crystalline inclusion-containing magnetic microstructure.

The various embodiments described herein provide a large length scale single crystal grain growth response in thin sheet form. In one embodiment, grain size appears limited only by the overall size of the sheet. In one embodiment, single crystal grained sheets are provided which have an area of at least 1 in² (about 6.45 cm²) or between about 1 and about 19 in² (6.45 to 122.58 cm²), including any range therebetween, with single crystal grained sheets up to about 19 in² (122.58 cm²) in size with a 0.015 (0.038 mm) in thickness. These large single crystals have the desired eta (η)-fiber texture orientation with the <001> magnetic easy axes oriented parallel to the RD. In one embodiment, the large single crystal areas in combination with the desired orientation result in magnetostrictions greater than about 200 ppm. In addition, in one embodiment, the composition and processing method can produce highly textured sheet material 0.015 in (0.0381 mm) thickness, or even thinner, which is ideal for devices operating at frequencies up to 50 kHz.

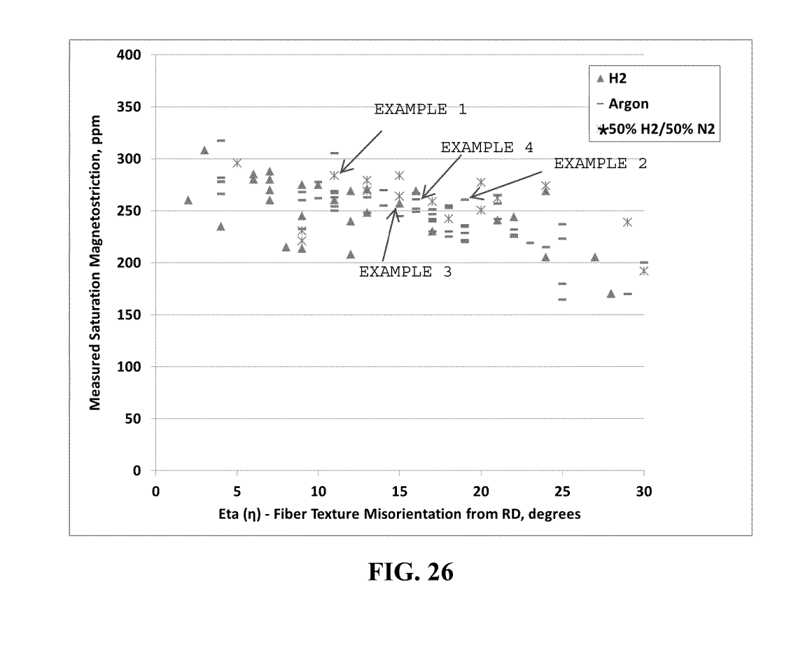

FIG. 26 is a graph showing measured saturation magneostriction versus misorientation angle for several representative samples. All samples represented in FIG. 26 were produced using the conditions and content of Examples 1-4 as well as variations of the conditions and content described in the examples. Most notably, three different heat treating atmospheres were utilized, each producing successful results with strong eta-fiber texture orientations within 30 degrees of the RD regardless of the environment used.

All publications, patents and patent documents are incorporated by reference herein, as though individually incorporated by reference, each in their entirety, as though individually incorporated by reference. In the case of any inconsistencies, the present disclosure, including any definitions therein, will prevail.

Although specific embodiments have been illustrated and described herein, it will be appreciated by those of ordinary skill in the art that any procedure that is calculated to achieve the same purpose may be substituted for the specific embodiments shown. For example, although the various embodiments have been described in terms of X, Y may also be possible. This application is intended to cover any adaptations or variations of the present subject matter. Therefore, it is manifestly intended that embodiments of this invention be limited only by the claims and the equivalents thereof.

1. A product comprising a single or near-single crystalline inclusion-containing magnetic microstructure comprising a Galfenol-carbide microstructure.

2. The product of claim 1 comprising one or more thin sheets.

3. (canceled)

4. The product of claim 3 wherein an inclusion in the inclusion-containing magnetic microstructure is niobium carbide.

5. The product of claim 4 wherein an amount of Nb₂C is included in the niobium carbide.

6. The product of claim 1 having an eta (η)-fiber texture greater than about 45.3 area % up to about 100 area % and a misorientation of less than about 30 degrees.

7. The product of claim 1 having a magnetostriction between about 200.1 ppm and about 400 ppm.

8. The product of claim 1 having a grain diameter in the rolling direction (RD)-transverse direction (TD) plane of at least about 10 mm and a thickness of no more than about 3 mm.

9. The product of claim 8 wherein the thickness is no more than about 0.381 mm.

10. The product of claim 1 having an operating frequency from about direct current (DC) to about 30 kHz.

11. The product of claim 10 wherein between about 230 and about 1400 ppmw of C (0.1 to 0.68 at %) is present and the AGG is moderate to strong.

12. The product of claim 11 comprising (Fe—Ga)₉₉(Nb)_{0.5}(C)_{0.5}.

13. The product of claim 9 configured for use in a device comprising an actuator, sensor or energy harvester.

14. The product of claim 13 wherein the energy harvester is a motor mount configured to convert motor vibrations from a motor into electrical energy.

15. A method of making one or more thin sheets comprising:
combining one or more form factor components with a dopant, a magnetic material, a magnetic material performance enhancer and a precipitate former to produce a melted alloy, wherein the dopant is selected from carbon (C), nitrogen (N), born (B), sulfur (S) and combinations thereof;
casting the melted alloy into a mold to produce at least one ingot;
optionally further processing the at least one ingot;
thickness reducing and annealing the at least one ingot to produce one or more annealed sheets; and
texture annealing the one or more annealed sheets to produce abnormal grain growth (AGG) in the one or more thin sheets, each of the one or more thin sheets containing a single or near-single crystalline inclusion-containing magnetic microstructure.

16. The method of claim 15 wherein the form factor component comprises shim stock formed into a thin walled closed cylinder.

17. (canceled)

18. The method of claim 15 wherein the dopant is carbon added as an Fe—C alloy in a range of between 1.5 wt % and 3.5 wt %.

19. The method of claim 15 wherein the texture annealing is performed at a dwell temperature from about 1100° C. to about 1250° C. and a dwell time of less than about 12 hrs.

20. The method of claim 15 wherein the magnetic material is iron and the magnetic material performance enhancer is selected from Gallium (Ga), Aluminum (Al), Molybdenum (Mo), Germanium (Ge), Tin (Sn), Silicon (Si), Beryllium (Be) and combinations thereof.

21. The method of claim 20 wherein the magnetic material performance enhancer is Gallium added in a range of between about 0.1 wt % (0.08 at %) and about 24 wt % (20.2 at %).

22. The method of claim 21 wherein the precipitate former is selected from titanium (Ti), molybdenum (Mo), tungsten (W), tantalum (Ta) and combinations thereof.

23. The method of claim 22 wherein the inclusion-containing magnetic microstructure is a Galfenol-carbide microstructure.

24. The method of claim 23 wherein the texture annealing is performed in an environment selected from hydrogen, hydrogen and nitrogen, argon, and combinations thereof.

25. A product made according to the method of claim 24.

26. (canceled)

27. The method of claim 15 wherein the melting is induction melting performed under a vacuum or partial vacuum.

28. A composition comprising:
a magnetic microstructure having a composition formula of: (Fe—Ga—Al—Mo—Ge—Sn—Si—Be)ₐ(Nb_{d}—Ti_{d}—Mo_{d}—Ta_{d}—W_{d})_{b}(C—N—B—S)_{c} wherein a≧98, b≦1, c≦1, d≦2 and a+b+c=100.

29. The composition of claim 28 wherein d=1 or 2.

30. The composition of claim 29 comprising (Fe—Ga)₉₉(Nb)_{0.5}(C)_{0.5}.

31. A device comprising:
a housing; and
one or more thin sheets contained within the housing, each of the one or more sheets containing a single or near-single crystalline inclusion-containing magnetic microstructure comprising a Galfenol-carbide microstructure.

32. The device of claim 31 comprising an actuator, sensor or energy harvester.

33. The device of claim 32 wherein the energy harvester is a motor mount configured to convert motor vibrations from a motor into electrical energy.
